(19) United States
(12) Patent Application Publication
(10) Pub. No.: US 2010/0119835 A1
(43) Pub. Date: May 13, 2010

(54) PHOTOCURABLE COMPOSITIONS FOR PREPARING ABS-LIKE ARTICLES

(75) Inventors: Laurence Messe, Blotzheim (FR); Loic Messe, Blotzheim (FR); Carole Chapelat, Saint-Louis (FR); Ranjana Patel, Little Hallingbury Essex (GB)

Correspondence Address: HUNTSMAN INTERNATIONAL LLC, LEGAL DEPARTMENT, 10003 WOODLOCH FOREST DRIVE, THE WOODLANDS, TX, 77380, US

(73) Assignee: Huntsman International LLC, The Woodlands, TX (US)

(21) Appl. No.: 12/530,899

(22) PCT Filed: Mar. 7, 2008
(86) PCT No.: PCT/EP08/52757

§ 371 Date: Sep. 11, 2009

(30) Foreign Application Priority Data
Mar. 14, 2007 (EP) 07005267.5

(51) Int. Cl. C08L 63/00; G03F 7/004; G03F 7/20; B32B 27/38

(52) U.S. Cl. 428/414; 430/280.1; 430/322

(57) ABSTRACT

The present invention relates to a photocurable composition comprising:
(a) 30-80% by weight of an epoxy-containing component
(b) 5 to 65% by weight of a compound containing an oxetane ring in its molecule;
(c) 1-25% by weight of a polyol having a molecular weight Mw of 2.000 or higher,
(d) an antimony-free cationic photoinitiator.
   wherein the percent by weight is based on the total weight of the photocurable composition.

The curable resin composition can be used for photocurable coatings per se and in specific for stereolithography and other such three dimensional printing applications where a 3D object is formed.

### FIELD OF THE INVENTION

The present invention is directed to a clear, low viscosity photocurable composition comprising an epoxy compound, a compound containing an oxetane ring in its molecule, a polyol containing mixture and a cationic photoinitiator and a process for producing opaque three-dimensional articles using said composition in the presence of rapid prototyping techniques.

### BACKGROUND OF THE INVENTION

Liquid-based Solid Imaging is a process whereby a photoformable liquid is coated into a thin layer upon a surface and exposed imagewise to actinic radiation, for example UV directed by laser for StereoLithography, such that the liquid solidifies imagewise. Subsequently, new thin layers of photoformable liquids are coated onto previous layers of liquid or previously solidified sections. The new layers are then exposed imagewise in order to solidify portions imagewise and in order to induce adhesion between portions of the new hardened region and portions of the previously hardened region. Each imagewise exposure is of a shape that relates to a pertinent cross-section of a photohardened object such that when all the layers have been coated and all the exposures have been completed, an integral photohardened object can be removed from the surrounding liquid composition. In some applications, it is beneficial to view the partially completed article under the liquid resin surface during the building of the article to allow for the determination of whether to abort the build or modify the building parameters on subsequent layers or future builds.

One of the most important advantages of the solid imaging process is the ability to rapidly produce actual articles that have been designed by computer aided design. A significant amount of progress has been made with compositions and processes that have been adapted to improve the accuracy of the articles produced. Also, composition developers have made significant progress toward improving individual properties such as the modulus or Heat Deflection Temperature (also called HDT being the temperature at which a sample of material deforms under a specified load) of the photohardened articles. Typically, a material with a higher HDT will perform better, that is, resist distortion better, in high-heat situations.

It would be desirable to produce a clear, low viscosity photocurable composition which, upon cure in a stereolithography process, produces an opaque article having the look and feel of the manufacturing material acrylonitrile-butadiene-styrene (“ABS”).

It is known to put various materials in the UV curable resins in order to achieve an opaque article for example by phase separation. Especially important for the laser based stereolithography process are formulations based on epoxy-acrylic resin mixtures. These formulations further require tougheners to produced balanced mechanical properties such as hydroxy containing ‘toughener’ from either a hydroxy polyester, polyether or polyurethane.

The patent application WO 00/63272 discloses a photocurable resin composition for the production of three-dimensional objects comprising an oxetane compound, an epoxy compound, a photoacid generator, elastomer particles with an average particle diameter of 10-700 nm, a polyol compound, an ethylenically unsaturated monomer and a radical photopolymerization initiator.

In the previous state of the art, there is no specific mention of examples of mixed polyols in epoxy-acrylic hybrids which allow differential and preferential separation of toughening microphase domains. These types of clear compositions which go opague are important as low viscosity, needed in operation of the equipment, for example an SL machine, can be achieved, yet yield desired high toughness. Pre-formed tougheners usually cannot be loaded up in effective amounts due to increases in viscosity.

### SUMMARY OF THE INVENTION

Users now desire to view the partially completed part under the resin surface during the part building. Doing so, enables them to make decisions about aborting the build or modifying the build parameters on subsequent layers or future builds. Clear curing or opaque liquid resins prevent this highly desirable property.

Also, agents which cause opaque liquids can cause problems for the SL resin. Some additives have been found to cause bubbles. In other cases, they may require higher than optimum viscosity.

In addition to above, there is an increasing need for improved performance of rapid protyping parts. The present invention not only provides resins that change colour during cure, but also the final parts present better mechanical properties and thermal resistance. They also have the look of a white thermoplastic, which is a desired property for a large number of users.

Requirement for UV curable stereolithography resins which go from clear to opaque is a new desire from customers.

There is still a need for improved photocurable resin compositions for the use in stereolithography. The uncured resin compositions shall have a low viscosity and result in product with good mechanical properties and high accuracy. A further desire is that the uncured resin is a clear liquid which turns to opaque after curing.

### DETAILED DESCRIPTION OF THE INVENTION

The present invention relates to a photocurable composition comprising:
(a) 30-80% by weight of an epoxy-containing component
(b) 5 to 65% by weight of a compound containing an oxetane ring in its molecule;
(c) 1-25% by weight of a polyol having a molecular weight Mw of 2.000 and higher.
(d) an antimony-free cationic photoinitiator.
   wherein the percent by weight is based on the total weight of the photocurable composition.

It has been surprisingly found that the combination of components (a) to (d) results in a photocurable composition the composition is clear and possesses a viscosity lower than those known from the state of art. The composition according to the invention allow fast laser curing and yield opaque three dimensional articles having an excellent balance of toughness, flexibility and a high heat deflection temperature similar to ABS.

In particular, the use of compounds containing one or more oxetane rings in its molecule supports the phase separation of the polyol during UV-curing, causing the clear, homogeneous liquid resin to turn into a white solid. Surprisingly, not only the appearance of the product is improved, the inventive combination of components (a) to (d) leads also to much improved mechanical properties.

The molecular weight given for the components of the claimed composition is meant as being the weight average molecular weight Mw. The Mw can be determined via HPLC, GPC or SEC which are analytical techniques well known to persons skilled in the art.

Epoxy Containing Component (a)

As a first component (a), the photocurable composition of the present invention includes from 30 to 80% by weight, preferably 40-80% by weight, based on the total weight of the photocurable composition, of one or more epoxy-containing compound. Typically, the epoxy-containing compound has at least one, preferably two or more epoxy groups. It may have one or more additional functional groups capable of reacting via or as a result of a ring-opening mechanism to form a polymeric network. Examples of such functional groups include oxirane-(epoxide), tetrahydrofuran- and lactone-rings in the molecule. Such compounds may have an aliphatic, aromatic, cycloaliphatic, araliphatic or heterocyclic structure and they may contain the ring groups as side groups, or the epoxide group can form part of an alicyclic or heterocyclic ring system. For the avoidance of doubt, in case an epoxy containing compound (a) has additional functional groups, it is nevertheless counted as epoxy containing component (a).

In one embodiment, preferred epoxy-containing compounds suitable for use in the present invention are non-glycidyl epoxies. These epoxies may be linear, branched, or cyclic in structure. For example, there may be included one or more epoxide compounds in which the epoxide groups form part of an alicyclic or heterocyclic ring system. Others include an epoxy-containing compound with at least one epoxycyclohexyl group that is bonded directly or indirectly to a group containing at least one silicon atom. Still others include epoxides which contain one or more cyclohexene oxide groups and epoxides which contain one or more cyclopentene oxide groups.

Particularly suitable non-glycidyl epoxies include the following difunctional non-glycidyl epoxide compounds in which the epoxide groups form part of an alicyclic or heterocyclic ring system: bis(2,3-epoxycyclopentyl)ether, 1,2-bis(2,3-epoxycyclopentyloxy)ethane, 3,4-epoxycyclohexyl-methyl 3,4-epoxycyclohexanecarboxylate, 3,4-epoxy-6-methyl-cyclohexyl-methyl 3,4-epoxy-6-methylcyclohexanecarboxylate, di(3,4-epoxycyclohexylmethyl)hexanedioate, di(3,4-epoxy-6-methylcyclohexylmethyl)hexanedioate, ethylenebis(3,4-epoxycyclohexanecarboxylate, ethanediol di(3,4-epoxycyclohexylmethyl)ether, vinylcyclohexene dioxide, dicyclopentadiene diepoxide or 2-(3,4-epoxycyclohexyl-5,5-spiro-3,4-epoxy)cyclohexane-1,3-dioxane, and 2,2′-Bis-(3,4-epoxy-cyclohexyl)-propane.

Highly preferred difunctional non-glycidyl epoxies include cycloaliphatic difunctional non-glycidyl epoxies, such as 3,4-epoxycyclohexyl-methyl 3′,4′-epoxycyclohexanecarboxylate and 2,2′-Bis-(3,4-epoxy-cyclohexyl)-propane, with the former being most preferred.

In another embodiment, the epoxy-containing compound is a polyglycidyl ether, poly(β-methylglycidyl)ether, polyglycidyl ester or poly(β-methylglycidyl)ester.

Particularly important representatives of polyglycidyl ethers or poly(β-methylglycidyl)ethers are based on monocyclic phenols, for example, on resorcinol or hydroquinone, or polycyclic phenols, for example, on bis(4-hydroxyphenyl)methane (bisphenol F), 2,2-bis(4-hydroxyphenyl)propane (bisphenol A), or on condensation products, obtained under acidic conditions, of phenols or cresols with formaldehyde, such as phenol novolaks and cresol novolaks. Examples of suitable polyglycidyl ethers include trimethylolpropane triglycidyl ether, triglycidyl ether of polypropoxylated glycerol, and diglycidyl ether of 1,4-cyclohexanedimethanol. Examples of particularly preferred polyglycidyl ethers include diglycidyl ethers based on bisphenol A and bisphenol F and mixtures thereof. In a preferred embodiment, polyglycidyl ethers or poly(β-methylglycidyl)ethers of hydrogenated versions of above monocyclic phenols or polycyclic phenols are used.

Epoxy-containing component (a) may also be derived from polyglycidyl and poly(β-methylglycidyl)esters of polycarboxylic acids. The polycarboxylic acid can be aliphatic, such as, for example, glutaric acid, adipic acid and the like; cycloaliphatic, such as, for example, tetrahydrophthalic acid; or aromatic, such as, for example, phthalic acid, isophthalic acid, trimellitic acid, or pyromellitic acid.

In another embodiment, the epoxy compound is a poly(N-glycidyl) compound or poly(S-glycidyl) compound. Poly(N-glycidyl) compounds are obtainable, for example, by dehydrochlorination of the reaction products of epichlorohydrin with amines containing at least two amine hydrogen atoms. These amines may, for example, be n-butylamine, aniline, toluidine, m-xylylenediamine, bis(4-aminophenyl)methane or bis(4-methylaminophenyl)-methane. However, other examples of poly(N-glycidyl) compounds include N,N′-diglycidyl derivatives of cycloalkyleneureas, such as ethyleneurea or 1,3-propyleneurea, and N,N′-diglycidyl derivatives of hydantoins, such as of 5,5-dimethylhydantoin. Examples of Poly(S-glycidyl) compounds are di-S-glycidyl derivatives derived from dithiols, for example ethane-1,2-dithiol or bis(4-mercaptomethylphen-yl)ether.

It is also possible to employ epoxy-containing compounds in which the 1,2-epoxide groups are attached to different heteroatoms or functional groups. Examples of these compounds include the N,N,O-triglycidyl derivative of 4-aminophenol, the glycidyl ether/glycidyl ester of salicylic acid, N-glycidyl-N′-(2-glycidyloxypropyl)-5,5-dimethylhydantoin or 2-glycidyloxy-1,3-bis(5,5-dimethyl-1-glycidylhydantoin-3-yl)propane.

Other epoxide derivatives may be employed, such as vinyl cyclohexene dioxide, vinyl cyclohexene monoxide, 3,4-epoxy-6-methyl cyclohexylmethyl 9,10-epoxystearate, 1,2-bis(2,3-epoxy-2-methylpropoxy)ethane, and the like.

Also conceivable is the use of liquid pre-reacted adducts of epoxy-containing compounds, such as those mentioned above, with hardeners for epoxy resins. It is of course also possible to use liquid mixtures of liquid or solid epoxy resins in the compositions according to this invention.

Preferred epoxy components are based on hydrogenated or perhydrogenated aromatic compounds such as perhydrogenated bisphenol A or on cycloaliphatic glycidyl epoxy compounds. Hydrogenated or perhydrogenated aromatic means the aromatic double bonds are partially or fully hydrogenated. The following are examples of commercial epoxy products suitable for use in the present invention: Uvacure® 1500 (3,4-epoxycyclohexylmethyl-3′,-4′-epoxycyclohexanecarboxylate, supplied by UCB Chemicals Corp.); Heloxy™ 48 (trimethylol propane triglycidyl ether, supplied by Resolution Performance Products LLC); Heloxy™ 107 (diglycidyl ether of cyclohexanedimethanol, supplied by Resolution Performance Products LLC); Uvacure® 1501 and 1502 are proprietary cycloaliphatic epoxides supplied by UCB Surface Specialties of Smyrna, Ga.; Uvacure® 1530-1534 are cycloaliphatic epoxides blended with a proprietary polyol; Uvacure® 1561 and Uvacure® 1562 are proprietary cycloaliphatic epoxides that have a (meth)acrylic unsaturation in them; Cyracure™ UVR-6100, -6105 and -6110 (are all 3,4-epoxycyclohexylmethyl-3′,4′-epoxycyclohexanecarboxylate); Cyracure™ UVR-6128 (Bis(3,4-epoxycyclohexyl) Adipate), Cyracure™ UVR-6200, Cyracure™ UVR-6216 (1,2-Epoxyhexadecane, supplied by Union Carbide Corp. of Danbury, Conn.); Araldite® CY 179 (3,4-epoxycyclohexylmethyl-3′,4′-epoxycyclohexanecarboxylate); PY 284 (digycidyl hexahydrophthalate polymer); Celoxide™ 2021 (3,4-epoxycyclohexyl methyl-3′,4′-epoxycyclohexyl carboxylate), Celoxide™ 2021 P (3′-4′-Epoxycyclohexanemethyl 3′-4′-Epoxycyclohexyl-carboxylate); Celoxide™ 2081 (3′-4′-Epoxycyclohexanemethyl 3′-4′-Epoxycyclohexyl-carboxylate modified caprolactone); Celoxide™ 2083, Celoxide™ 2085, Celoxide™ 2000, Celoxide™ 3000, Cyclomer A200 (3,4-Epoxy-Cyclohexylmethyl-Acrylate); Cyclomer M-100 (3,4-Epoxy-Cyclohexylmethyl-Methacrylate); Epolead® GT-300, Epolead® GT-302, Epolead® GT-400, Epolead® 401, and Epolead® 403 (by Daicel Chemical Industries Co., Ltd.). Epalloy® 5000 (epoxidized hydrogenated bisphenol A, supplied by CVC Specialties Chemicals, Inc.) Other hydrogenated aromatic glycidyl epoxies may be used.

The photocurable composition of the present invention may include mixtures of the cationically curable compounds described above.

Compound Containing an oxetane Ring (b)

Further the composition of present invention contains a compound containing at least one oxetane ring in its molecule as component (b). Like epoxides, such compounds can be polymerized or crosslinked by radiation from light in the presence of cationic polymerization initiators.

The inventors found that the oxetane containing compound has not only influence on the polymerization system. It seems that oxetane, especially oxetane compounds comprising one or more hydroxyl groups enhances the phase separation of the polyol-containing component, so that the amount of polyol-containing component can be reduced. In case an oxetane compound containing one or more hydroxyl group is used such component is counted as oxetane component (b).

The oxetane compound (b) is present in amounts from 5 to 65% by weight, preferably in an amount from 5 to 40% by weight, and most preferably in an amount from 5 to 25% by weight, based on the photocurable composition.

The oxetane compound may contain 1 or more oxetane groups. Preferably, the compound has less than 20, and in particular less than 10 oxetane groups. In particularly preferred embodiments the oxetane compound has two oxetane groups. It may also be useful to use mixtures of oxetane compounds, in particular those having 1, 2, 3, 4 or 5 oxetane groups. The oxetane compound preferably has a molecular weight Mw of about 100 or more, preferably of about 200 or more. Generally, this compound will have a molecular weight Mw of about 10,000 or lower, preferably of about 5,000 or lower.

The oxetane groups of compounds (b) preferably constitute the terminus of radiation curable oligomers having a phenyl, (oligo)-bis-phenyl, polysiloxane or polyether, backbone. Examples of polyethers are e.g. poly-THF, polypropylene glycol, alkoxylated trimethylolpropane, alkoxylated pentaerytritol and the like.

Preferably, the component (b) has one or more groups according to formula I

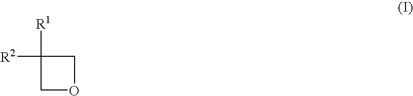

wherein R¹ is a group of the formula II

CH₂—X—R³ (II)
wherein X is 0 or S and
R² and R³ are the remainder of the molecule.

Examples of the compound having one oxetane ring used as component (b) are compounds according to formula (I), wherein X represents an oxygen atom or a sulfur atom, R² represents a hydrogen atom; fluorine atom; alkyl group having from 1 to 6 carbon atoms such as a methyl group, ethyl group, propyl group, butyl group, or the like; fluoroalkyl group having from 1 to 6 carbon atoms such as a trifluromethyl group, perfluoroethyl group, perfluoropropyl group, or the like; aryl group having from 6 to 18 carbon atoms such as a phenyl group, naphthyl group, or the like; furyl group, or thienyl group, and R³ represents a hydrogen atom, alkyl group having from 1 to 6 carbon atoms such as a methyl group, ethyl group, propyl group, butyl group, or the like; alkenyl group having from 2 to 6 carbon atoms such as an 1-propenyl group, 2-propenyl group, 2-methyl-1-propenyl group, 2-methyl-2-propenyl group, 1-butenyl group, 2-butenyl group, 3-butenyl group, or the like; aryl group having from 6 to 18 carbon atoms such as a phenyl group, naphthyl group, anthonyl group, phenanthryl group, or the like; aralkyl group having from 7 to 18 carbon atoms which may be either substituted or unsubstituted, such as a benzyl group, fluorobenzyl group, methoxybenzyl group, phenethyl group, styryl group, cinnamyl group, ethoxybenzyl group, or the like; group having other aromatic groups such as an aryloxyalkyl group including a phenoxymethyl group, phenoxyethyl group or the like; alkylcarbonyl group having from 2 to 6 carbon atoms such as an ethylcarbonyl group, propylcarbonyl group, butylcarbonyl group, or the like; alkoxycarbonyl group having from 2 to 6 carbon atoms such as an ethoxycarbonyl group, propoxycarbonyl group, butoxycarbonyl group, or the like; or N-alkylcarbamoyl group having from 2 to 6 carbon atoms such as an ethylcarbamoyl group, propylcarbamoyl group, butylcarbamoyl group, pentylcarbamoil group, or the like.

The oxetane compounds having two oxetane rings, include for example those compounds represented by the following formula (III)

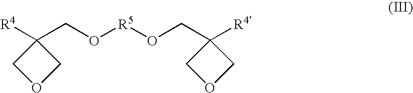

wherein R⁴ and R^{4′} independently represent a group of the above formula (II), R⁵ is a linear or branched alkylene group having from 1 to 20 carbon atoms such as an ethylene group, propylene group, butylene group, or the like; linear or branched poly(alkylenoxy) group having from 1 to 120 carbon atoms such as poly(ethylenoxy) group, poly(propylenoxy) group, or the like; linear or branched unsaturated hydrocarbon group such as a propenylene group, methylpropenylene group, butenylene group, or the like; carbonyl group, alkylene group containing a carbonyl group, alkylene group containing a carboxyl group in the middle of a molecular chain, and alkylene group containing a carbamoyl group in the middle of a molecular chain. Also in the compounds of formula (III), R⁵ may be a polyvalent group represented by any one of the following formulas (IV) to (VI):

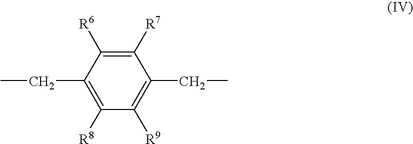

wherein R⁶, R⁷, R⁸ and R⁹ represent independently from each other an hydrogen atom; alkyl group having from 1 to 4 carbon atoms such as a methyl group, ethyl group, propyl group, butyl group, or the like; alkoxy group having from 1 to 4 carbon atoms such as a methoxy group, ethoxy group, propyoxy group, butoxy group, or the like; halogen atom such as a chlorine atom, bromine atom, or the like; nitro group, cyano group, mercapto group, lower alkylcarboxyl group, carboxyl group, or carbamoyl group,

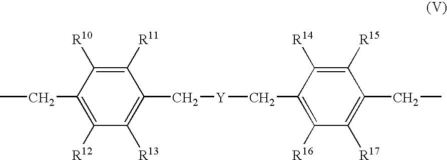

wherein Y represents an oxygen atom, sulfur atom, methylene group, and groups represented by the formulae —NH—, —SO—, —SO₂—, —C(CF₃)₂—, or —C(CH₃)₂—, and R¹⁰ to R¹⁷ independently may have the same meaning as R⁶ to R⁹ as defined above,

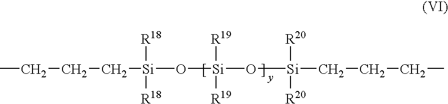

wherein R¹⁸ and R²⁰ independently represent an alkyl group having from 1 to 4 carbon atoms such as a methyl group, ethyl group, propyl group, butyl group, or the like, or aryl group having from 6 to 18 carbon atoms such as a phenyl group, naphthyl group, or the like, y denotes an integer of from 0 to 200, and R¹⁹ represents an alkyl group having from 1 to 4 carbon atoms such as a methyl group, ethyl group, propyl group, butyl group, or the like or aryl group having from 6 to 18 carbon atoms such as a phenyl group, naphthyl group, or the like. Alternatively, R¹⁹ may be a group represented by the following formula (VII)

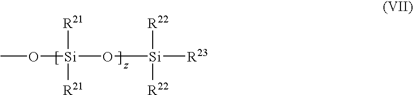

wherein R²¹, R²² and R²³ independently represent an alkyl group having from 1 to 4 carbon atoms such as a methyl group, ethyl group, propyl group, butyl group, or the like, or aryl group having from 6 to 18 carbon atoms such as a phenyl group, naphthyl group, or the like, and z is an integer of from 0 to 100.

Examples of preferred compounds containing one oxetane ring in its molecule are 3-ethyl-3-hydroxymethyloxetane, 3-(meth)allyloxymethyl-3-ethyloxetane, (3-ethyl-3-oxetanylmethoxy)-methylbenzene, 4-fluoro-[1-(3-ethyl-3-oxetanylmethoxy)methyl]benzene, 4-methoxy-[1-(3-ethyl-3-oxetanylmethoxy)methyl]benzene, [1-(3-ethyl-3-oxetanylmethoxy)ethyl]phenyl ether, isobutoxymethyl(3-ethyl-3-oxetanylmethyl)ether, isobomyloxyethyl(3-ethyl-3-oxetanylmethyl)ether, isobomyl(3-ethyl-3-oxetanylmethyl)ether, 2-ethylhexyl(3-ethyl-3-oxetanylmethyl)ether, ethyldiethylene glycol(3-ethyl-3-oxetanylmethyl)ether, dicyclopentadiene(3-ethyl-3-oxetanyl)methyl)ether, dicyclopentenyloxyethyl(3-ethyl-3-oxetanylmethyl)ether, dicyclopentenyl(3-ethyl-3-oxetanylmethyl)ether, tetrahydrofurfuryl(3-ethyl-3-oxetanylmethyl)ether, tetrabromophenyl(3-ethyl-3-oxetanylmethyl)ether, 2-tetrabromophenoxyethyl(3-ethyl-3-oxetanylmethyl)ether, tribromophenyl(3-ethyl-3-oxetanylmethyl)ether, 2-tribromophenoxyethyl(3-ethyl-3-oxetanylmethyl)ether, 2-hydroxyethyl(3-ethyl-3-oxetanyl methyl)ether, 2-hydroxypropyl(3-ethyl-3-oxetanylmethyl)ether, butoxyethyl(3-ethyl-3-oxetanylmethyl)ether, pentachlorophenyl(3-ethyl-3-oxetanylmethyl)ether, pentabromophenyl(3-ethyl-3-oxetanylmethyl)ether, bornyl(3-ethyl-3-oxetanylmethyl)ether, and the like. Other examples of oxetane compounds suitable for use include trimethylene oxide, 3,3-dimethyloxetane, 3,3-dichloromethyloxetane, 3,3-[1,4-phenylene-bis(methyleneoxymethylene)]-bis(3-ethyloxetane), 3-ethyl-3-hydroxymethyl-oxetane, and bis-[(1-ethyl(3-oxetanyl)methyl)]ether.

Examples of compounds having two or more oxetane rings in the compound which may be used in the present invention include: 3,7-bis(3-oxetanyl)-5-oxa-nonane, 3,3′-(1,3-(2-methylenyl)propanediylbis(oxymethylene))bis-(3-ethyloxetane), 1,4-bis[(3-ethyl-3-oxetanylmethoxy)methyl]benzene, 1,2-bis[(3-ethyl-3-oxetanylmethoxy)methyl]ethane, 1,3-bis[(3-ethyl-3-oxetanylmethoxy)methy]propane, ethylene glycol bis(3-ethyl-3-oxetanylmethyl)ether, dicyclopentenyl bis(3-ethyl-3oxetanylmethyl)ether, triethylene glycol bis(3-ethyl-3-oxetanylmethyl)ether, tetraethylene glycol bis(3-ethyl-3-oxetanylmethyl)ether, tricyclodecanediyldimethylene(3-ethyl-3-oxetanylmethyl)ether, trimethylolpropane tris(3-ethyl-3-oxetanylmethyl)ether, 1,4-bis(3-ethyl-3-oxetanylmethoxy)butane, 1,6-bis(3-ethyl-3-oxetanylmethoxy)hexane, pentaerythritol tris(3-ethyl-3-oxetanylmethyl)ether, pentaerythritol tetrakis(3-ethyl-3-oxetanylmethyl)ether, polyethylene glycol bis(3-ethyl-3-oxetanylmethyl)ether, dipentaerythritol hexakis(3-ethyl-3-oxetanylmethyl)ether, dipentaerythritol pentakis(3-ethyl-3-oxetanylmethyl)ether, dipentaerythritol tetrakis(3-ethyl-3-oxetanylmethyl)ether, caprolactone-modified dipentaerythritol hexakis(3-ethyl-3-oxetanylmethyl)ether, caprolactone-modified dipentaerythritol pentakis(3-ethyl-3-oxetanylmethyl)ether, ditrimethylolpropane tetrakis(3-ethyl-3-oxetanylmethyl)ether, EO-modified Bisphenol A bis(3-ethyl-3-oxetanylmethyl)ether, PO-modified Bisphenol A bis(3-ethyl-3-oxetanylmethyl)ether, EO-modified hydrogenated Bisphenol A bis(3-ethyl-3-oxetanylmethyl)ether, PO-modified hydrogenated Bisphenol A bis(3-ethyl-3-oxetanylmethyl)ether, EO-modified Bisphenol F (3-ethyl-3-oxetanylmethyl)ether, and the like.

Of the above compounds, it is preferable that the oxetane compounds have 1-10, preferably 1-4, and even more preferably 1 oxetane rings in the compound. Specifically, 3-ethyl-3-hydroxymethyl oxetane, (3-ethyl-3-oxetanylmethoxy)methylbenzene, 1,4-bis[(3-ethyl-3-oxetanylmethoxy)methyl]benzene, 1,2-bis(3-ethyl-3-oxetanylmethoxy)ethane and trimethylolpropane tris(3-ethyl-3-oxetanylmethyl)ether are preferably used. Commercially available oxetane compounds include Cyracure® UVR 6000 (available from Dow Chemical Co.) and Aron Oxetane OXT-101, OXT-121, OXT-211, OXT-212, OXT-221, OXT-610 and OX-SQ (available from Toagosei Co. Ltd.).

In a further preferred embodiment, the following oxetane compounds can be used in present invention:

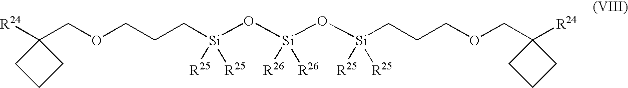

wherein
R²⁴ represents a hydrogen atom, fluorine atom, an alkyl group having 1-6 carbon atoms such as methyl group, ethyl group, propyl group and butyl group, a fluoroalkylalkyl group having 1-6 carbon atoms such as trifluoromethyl group, perfluoroethyl group, and perfluoropropyl group, an aryl group having 6-18 carbon atoms such as a phenyl group and naphthyl group, a furyl group, or a thienyl group;
R²⁵ represents an alkyl group having 1-4 carbon atoms or an aryl group having 6-18 carbon atoms for example a phenyl group or naphthyl group;
n is an integer from 0-200;
R²⁶ represents an alkyl group having 1-4 carbon atoms, an aryl group having 6-18 carbon atoms for example a phenyl group or naphthyl group, or a group shown by the following formula (IX):

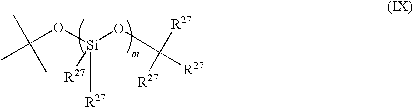

wherein R²⁷ represents an alkyl group having 1-4 carbon atoms, an aryl group having 6-18 carbon atoms for example a phenyl group or naphthyl group, and m is an integer from 0-100.

A specific example of the previously mentioned molecule (VIII) is:

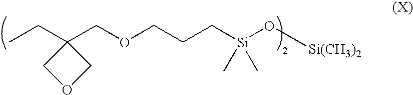

The following multifunctional ring molecules may also be used for the present invention:

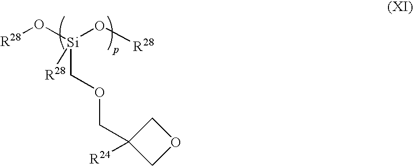

wherein R²⁸ represents an alkyl group having 1-4 carbon atoms or trialkylsilyl group (wherein each alkyl group individually is an alkyl group having 1-12 carbon atom), for example a trimethylsilyl group, triethylsilyl group, tripropylsilyl group, or tributylsilyl group, R²⁴ is the same as defined in the previous formula (VIII).

And p is an integer from 1-10.

A a specific example of the previously mentioned molecule (XI) is presented by formula XII:

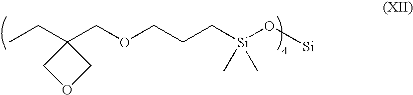

Polyol Containing Mixture (c)

In photocurable compositions, the polyol is usually soluble in the uncured composition and undergoes phase separation during UV-curing. In order to ensure proper phase separation, the molecular weight Mw of polyol (c) is 2.000 or higher.

Component (c) can be a single polyol or a mixture of different polyols. Polyol means that the compound contains at least 2 OH groups. It can be aliphatic, alicyclic, or aromatic. The hydroxyl groups can be either primary, secondary, or tertiary.

This polyol can be a polyoxyalkylene polyol, polyester polyol, polyurethane polyol, hydroxyl-terminated polysiloxane, etc. It can be linear (difunctional polyol) or branched (trifunctional or higher functionality), or star-like (trifunctional or higher functionality). Examples of such polyoxyalkylene polyols include polyoxyethylene, i.e., polyethylene triols, polyoxypropylene, i.e., polypropylene triols and polyoxybutylene, i.e., polybutylene triols. Examples of such polyester polyols include polycaprolactone diols.

Preferred polyols have a molecular weight Mw of 5.000 or higher, more preferably of 7.500 or higher and in particular of 10.000 or higher.

It is known to the person skilled in the art that polyols of high molecular weights will undergo phase separation upon UV polymerisation of the formulation, due to the change in the interaction causing the long chains to become more and more incompatible with the matrix. Use of polyols as flexibilisers and tougheners usually results in a softening of the matrix, causing the tensile and flexural moduli to drop, and resulting in lower thermal resistance. These polyols also have high viscosity, and increase significantly the viscosity of the final compositions.

It was surprisingly found that the addition of an oxetane component (b) further enhances the phase separation of component (c), without degradation of the mechanical properties. The presence of component (b) also allows to reduce the amount of the component (c) as compared to the prior art.

Further, it has been found that the phase separation of high molecular weight polyols (component (c)) is enhanced by the presence of oxetane component (b) and that the domains formed in this manner provide a better toughening effect than in the absence of (b). We surprisingly found that in this manner, the parts produced had the appearance of a white thermoplastic, even though the starting liquid resin was clear, which adds value to the customer, and that the final objects manufactured were tough but retained rigidity, and had great thermal resistance. Additionally, the invention may provide all these benefits without any increase in viscosity, which is the well known drawback of toughening epoxy systems with polyols.

The photocurable composition is a clear liquid.

The term “liquid at 23° C.” as used within the present invention means that viscosities range between 1 and 3000 mPa·s at 30° C., measured with a Brookfield model RVT or Brookfield model LVT DV II, with spindle SC4-18 or SC4-21 according to the technical data sheet from Brookfield. The spindles can be used either on the RVT or LVT viscosimeter. The speed ranges between 0.5 and 100 rpm on the RVT viscosimeter and between 0.6 and 30 rpm on the LVT DV II viscosimeter.

Clear: by clear, me mean a lightness L* of 30 to 40 (or below). The definition of L* is given in the experimental section. Preferably, the composition of present invention has a L* above 40.

Typically its viscosity determined at 30° C. is below 1000 mPa·s. It forms under curing an opaque solid. Preferably this opaque cured solid has a Lightness L* (measured as defined hereinafter) of at least 65, more preferably at least 69. Solid parts with L* less than 65, appear hazy or opalescent to the eye, which is not preferred.

Commercially available poly(oxytetramethylene)diols include those available in the Polymeg® line (Penn Specialty Chemicals) and the polyTHF line from BASF, having a MW above 2000 g/mol (polyTHF 2000 and polyTHF 2900).

Commercially available polyether polyols include the Lupranol range from Elastrogran GMBH (Lupranol® balance 50, Lupranol® 1000, Lupranol® 2032, Lupranol® 2043, Lupranol® 2046, Lupranol® 2048, Lupranol® 2070, Lupranol® 2084, Lupranol® 2090, Lupranol® 2092, Lupranol® 2095, Lupranol® VP9289, Lupranol® VP9343 and Lupranol® VP9350).

Commercially available poly(oxypropylene) polyols include Arcol® polyol LG-56, Arcol® polyol E-351, Arcol® LHT-42, Acclaim® 4200, Acclaim® 6300, Acclaim® 8200 and Acclaim® 12200 (all from Bayer Materials Science)

Commercially available hydroxy-terminated polybutadienes are PolyBD® R-45HTLO from Sartomer.

Commercially available saturated aliphatic hydrogenated polyol includes the Krasol® range from Sartomer (Krasol®HLBH-P 2000, Krasol®LBH-2040, Krasol®LBH 3000, Krasol®LBH-P 5000)

Commercially available polyester polyols include the Tone™ range of polyols from Dow (Tone 0240, Tone 0249, Tone 0260, Tone 1241, Tone 1278, Tone 2241, Tone 5249, Tone 7241), the Desmophen® range from Bayer Materials Science (Desmophen® 2001-K, Desmophen® 2000, Desmophen® 2001-KS, Desmophen® 5035BT, Desmophen® 2502), Simulsol™ TOMB from Seppic.

Cationic Photoinitiator (d)

As component (d), the photocurable composition of the present invention includes at least one antimony-free cationic photoinitiator, preferably in an amount from about 0.2-10% by weight, based on the total weight of the photocurable composition. The cationic photoinitiator may be chosen from those commonly used to initiate cationic photopolymerization. Examples include onium salts with anions of weak nucleophilicity, e.g., halonium salts, iodosyl salts, sulfonium salts, sulfoxonium salts, or diazonium salts. Metallocene salts are also suitable as photoinitiators.

The antimony-free cationic photoinitiator may be chosen from those commonly used to initiate cationic photopolymerization. Examples include onium salts with anions of weak nucleophilicity, e.g., halonium salts, iodosyl salts, sulfonium salts, sulfoxonium salts, diazonium salts, pyrylium salts or pyridinium salts. Metallocene salts are also suitable as photoinitiators.

The antimony-free cationic photoinitiator may also be a dialkylphenylacylsulfonium salt. These antimony-free cationic photoinitiators have the general formula A₁(CA₂A₃OH)ₙ where A₁ is selected from phenyl, polycyclic aryl, and polycyclic heteroaryl, each optionally substituted with one or more electron donating groups, A₂ and A₃ are independently selected from hydrogen, alkyl, aryl, alkylaryl, substituted alkyl, substituted aryl and substituted alkylaryl and n is an integer from 1 to 10.

Preferred antimony-free cationic photoinitiators are compounds of the formula (I):

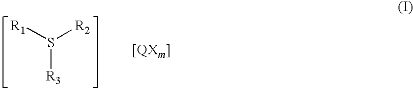

where
R₁, R₂and R₃ are each independently of one another C₆₋₁₈ aryl that is unsubstituted or substituted by suitable radicals,
Q is boron or phosphorus,
X is a halogen atom, and
m is an integer corresponding to the valence of Q plus 1.

Examples of C₆₋₁₈ aryl are phenyl, naphthyl, anthryl, and phenanthryl. Suitable radicals include alkyl, preferably C₁₋₆ alkyl, such as methyl, ethyl, n-propyl, isopropyl, n-butyl, sec-butyl, iso-butyl, tert-butyl, or the various pentyl or hexyl isomers, alkoxy, preferably C₁₋₆ alkoxy such as methoxy, ethoxy, propoxy, butoxy, pentyloxy, or hexyloxy, alkylthio, preferably C₁₋₆ alkylthio, such as methylthio, ethylthio, propylthio, butylthio, pentylthio, or hexylthio, halogen, such as fluorine, chlorine, bromine, or iodine, amino groups, cyano groups, nitro groups, or arylthio, such as phenylthio. Preferred QXₘ groups include BF₄ and PF₆. A further example of a QXₘ group suitable for use is a perfluorophenylborate, for example, tetrakis(perfluorophenyl)borate.

Examples of commercially available antimony-free cationic photoinitiators include: (1) hexafluorophosphate (PF₆) salts including (i) Cyracure® UVI-6992 (Dow Chemical Co.), CPI 6992 (Aceto Corp.), Esacure® 1064 (Lamberti s.p.a.) and Omnicat 432 (IGM Resins B.V.) which are triarylsulfonium hexafluorophosphate salts (a mixture of thio and bis salts); (ii) SP-55 (Asahi Denka Co. Ltd.), Degacure KI 85 (Degussa Corp.) and SarCat KI-85 (available from Sartomer Co. Inc.) which are triarylsulfonium hexafluorophosphate salts (bis salts); (iii) SP-150 (Asahi Denka Co. Ltd.) a Bis[4-(di(4-(2-hydroxyethyl)phenyl)sulphonio)-phenyl]sulphide bis-hexafluorophosphate; (iv) Esacure® 1187 (Lamberti s.p.a.) a modified sulfonium hexafluorophosphate salt; (v) metallocene salts including cumenyl cyclopentadienyl iron (II) hexafluorophosphate, Irgacure® 261 (Ciba Specialty Chemicals), Naphthalenylcyclopentadienyl iron (II) hexafluorophosphate, benzyl cyclopentadienyl iron (II) hexafluorophosphate, cyclopentadienyl carbazole iron (II) hexafluorophosphate; (vi) iodonium salts including UV1242 a bis(dodecylphenyl)iodonium hexafluorophosphate (Deuteron), UV2257 a bis(4-methylphenyl)iodonium hexafluorophosphate (Deuteron), and Omnicat 440 (IGM Resins B.V.), Irgacure® 250 (Ciba Specialty Chemicals) a (4-methylphenyl)(4-(2-methylpropyl)phenyl)iodonium hexafluorophosphate; (vii) thioxantene salts including Omnicat 550 (IGM Resins B.V.) a 10-biphenyl-4-yl-2-isopropyl-9-oxo-9H-thioxanthene-10ium hexafluorophosphate, Omnicat 650 (IGM Resins B.V.) an adduct of 10-biphenyl-4-yl-2-isopropyl-9-oxo-9H-thioxanthene-10ium hexafluorophosphate with a polyol; and (2) Pentafluorophenyl borate salts including Rhodorsil 2074 (Rhodia) a (totylcumyl)iodonium tetrakis(pentafluorophenyl)borate. The antimony-free cationic photoinitiator may contain one antimony-free cationic photoinitiator or a mixture of two or more antimony-free cationic photoinitiators.

The proportion of the antimony-free cationic photoinitiator in the photocurable composition may be at least about 0.1% by weight, preferably at least about 1% by weight, and even more preferably at least about 4% by weight based on the total weight of the photocurable composition. In another embodiment, the antimony-free cationic photoinitiator is present at most about 10% by weight, more preferably at most about 8% by weight, and even more preferably at most about 7% by weight based on the total weight of the photocurable composition. In yet another embodiment, the antimony-free cationic photoinitiator is present in the range of from about 0.1-10% by weight, preferably from about 0.5-8% by weight, and more preferably from about 2-7% by weight based on the total weight of the photocurable composition.

In a preferred embodiment, the cationic photoinitiator comprises a triarylsulfonium hexafluorophosphate salt.

Further Components

Free Radical Photoinitiator (e)

In addition to the cationic polymerization initiator, the photocurable composition of the present invention may include a free radical photoinitiator, preferably in an amount of from about 0.01-10% by weight, based on the total weight of the photocurable composition. The free radical photoinitiator may be chosen from those commonly used to initiate radical photopolymerization. Examples of free radical photoinitiators include benzoins, e.g., benzoin, benzoin ethers such as benzoin methyl ether, benzoin ethyl ether, benzoin isopropyl ether, benzoin phenyl ether, and benzoin acetate; acetophenones, e.g., acetophenone, 2,2-dimethoxyacetophenone, and 1,1-dichloroacetophenone; benzil ketals, e.g., benzil dimethylketal and benzil diethyl ketal; anthraquinones, e.g., 2-methylanthraquinone, 2-ethylailthraquinone, 2-tertbutylanthraquinone, 1-chloroanthraquinone and 2-amylanthraquinone; triphenylphosphine; benzoylphosphine oxides, e.g., 2,4,8-trimethylbenzoy-diphenylphosphine oxide (Luzirin TPO); bisacylphosphine oxides; benzophenones, e.g., benzophenone and 4,4′-bis(N,N′-dimethylamino)benzophenone; thioxanthones and xanthones; acridine derivatives; phenazine derivatives; quinoxaline derivatives; 1-phenyl-1,2-propanedione 2-O-benzoyl oxime; 4-(2-hydroxyethoxy)phenyl-(2-propyl)ketone (Irgacure® 2959); 1-aminophenyl ketones or 1-hydroxy phenyl ketones, e.g., 1-hydroxycyclohexyl phenyl ketone, 2-hydroxyisopropyl phenyl ketone, phenyl 1-hydroxyisopropyl ketone, and 4-isopropylphenyl 1-hydroxyisopropyl ketone.

Preferably, the free radical photoinitiator is a cyclohexyl phenyl ketone. More preferably, the cyclohexyl phenyl ketone is a 1-hydroxy phenyl ketone. Most preferably the 1-hydroxy phenyl ketone is 1-hydroxycyclohexyl phenyl ketone, e.g., Irgacure® 184.

Acrylate-Containing Compound (f)

Optionally the composition of present invention may comprise one or more (meth)acrylate-containing compounds. These compounds may be present from about 5-40% by weight, based on the total weight of the photocurable composition. “(Meth)acrylate” refers to an acrylate, a methacrylate, or a mixture thereof. The (meth)acrylate-containing compound preferably includes at least two (meth)acrylate groups, e.g. it is a di-, tri-, tetra- or pentafunctional monomeric or oligomeric aliphatic, cycloaliphatic, or aromatic (meth)acrylate.

In one embodiment, the acrylate-containing compound is a difunctional (meth)acrylate, for example, an aliphatic or aromatic difunctional (meth)acrylate. Examples of di(meth)acrylates include di(meth)acrylates of cycloaliphatic or aromatic diols such as 1,4-dihydroxymethylcyclohexane, 2,2-bis(4-hydroxycyclohexyl)propane, bis(4-hydroxycyclohexyl)methane, hydroquinone, 4,4′-dihydroxybiphenyl, Bisphenol A, Bisphenol F, Bisphenol S, ethoxylated or propoxylated Bisphenol A, ethoxylated or propoxylated Bisphenol F, and ethoxylated or propoxylated Bisphenol S. Di(meth)acrylates of this kind are known and some are commercially available, e.g., Ebecryl® 3700 (Bisphenol-A epoxy diacrylate) (supplied by UCB Surface Specialties). A particularly preferred di(meth)acrylate is a Bisphenol A-based epoxy diacrylate.

Alternatively, preferred di(meth)acrylates are acyclic aliphatic, hydrogenated aromatic or perhydrogenated aromatic (meth)acrylates. The meaning of hydrogenated or perhydrogenated aromatic is defined above. Di(meth)acrylates of this kind are generally known and include compounds of the following formulae

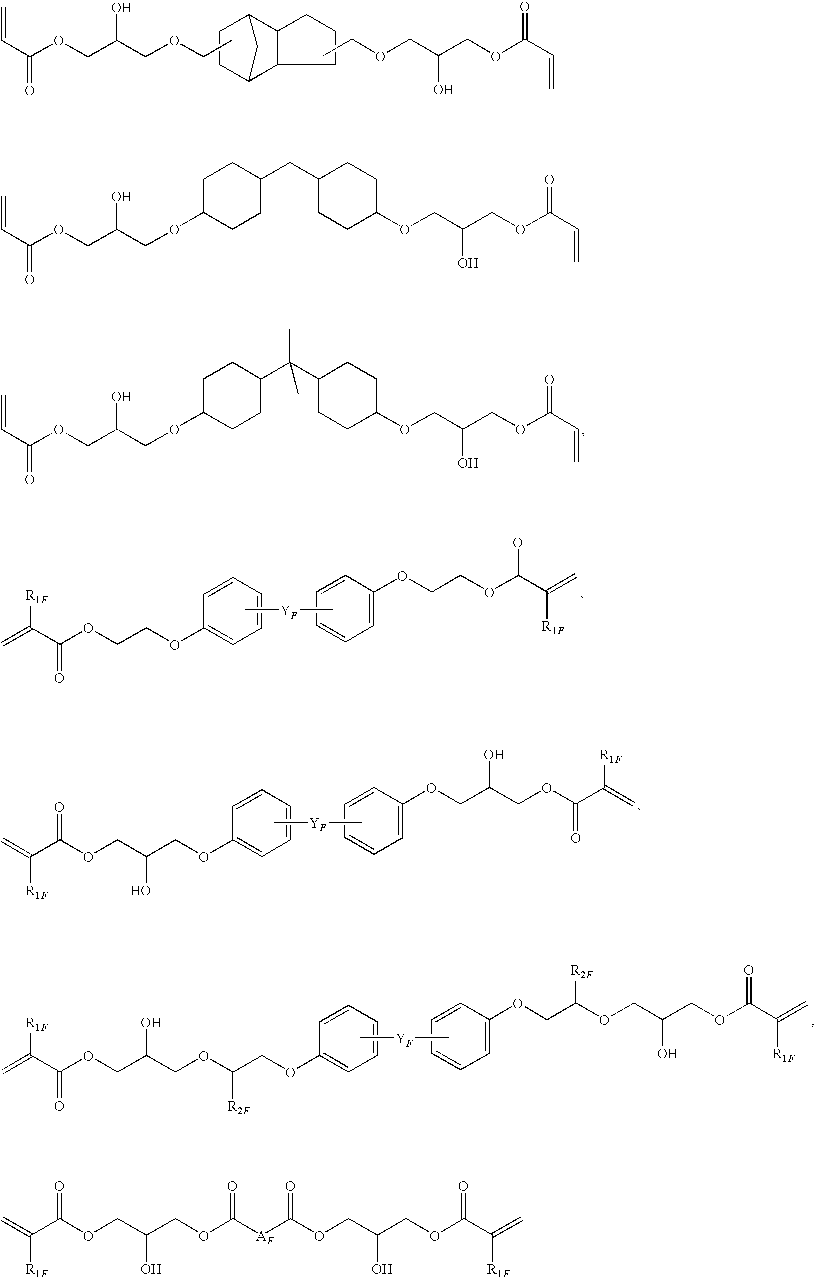

in which

R_{1F} is a hydrogen atom or methyl,

Y_{F} is a direct bond, C₁-C₆ alkylene, —S—, —O—, —SO—, —SO₂— or —CO—,

R_{2F} is a C₁-C₈ alkyl group, a phenyl group in which is unsubstituted or substituted by one or more C₁-C₄ alkyl groups, hydroxyl groups or halogen atoms, or is a radical of the formula —CH₂—OR_{3F} in which

R_{3F} is a C₁-C₈ alkyl group or phenyl group, and

A_{F} is a radical selected from the radicals of the formulae

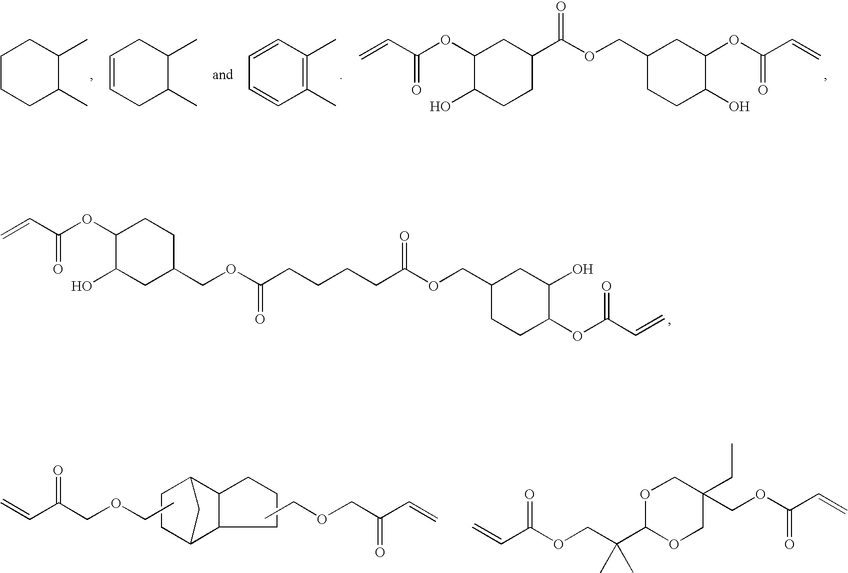

Some of the above shown compounds are commercially available, for example SR833S of Sartomer.

A poly(meth)acrylate suitable for the present invention may include a tri(meth)acrylate or higher functionalized (meth)acrylate. Examples are the tri(meth)acrylates of hexane-2,4,6-triol, glycerol, 1,1,1-trimethylolpropane, ethoxylated or propoxylated glycerol, and ethoxylated or propoxylated 1,1,1-trimethylolpropane. Other examples are the hydroxyl-containing tri(meth)acrylates obtained by reacting triepoxide compounds (e.g., the triglycidyl ethers of the triols listed above) with (meth)acrylic acid. Other examples are pentaerythritol tetraacrylate, bistrimethylolpropane tetraacrylate, pentaerythritol monohydroxytri(meth)acrylate, or dipentaerythritol monohydroxypenta(meth)acrylate. Examples of suitable aromatic tri(meth)acrylates are the reaction products of triglycidyl ethers of trihydric phenols, and phenol or cresol novolaks containing three hydroxyl groups, with (meth)acrylic acid.

Preferably, the acrylate-containing compound includes a compound having at least one terminal and/or at least one pendant (i.e., internal) unsaturated group and at least one terminal and/or at least one pendant hydroxyl group. The photocurable composition of the present invention may contain more than one such compound. In case an (meth)acrylate compound containing one or more hydroxyl group is used, such component is counted as acrylate component (f). Examples of such compounds include hydroxy mono(meth)acrylates, hydroxy poly(meth)acrylates, hydroxy monovinylethers Commercially available examples include: dipentaerythritol pentaacrylate (SR 399, supplied by SARTOMER Company); pentaerythritol triacrylate (SR 444, supplied by SARTOMER Company), SR508 (dipropylene glycol diacrylate), SR 833s (tricyclodecane dimethanol diacrylate), SR9003 (dipropoxylated neopentyl glycol diacrylate), ethoxylated trimethylolpropane triacrylate (SR499, supplied by SARTOMER company) and bisphenol A diglycidyl ether diacrylate (Ebecryl® 3700, supplied by UCB Surface Specialties), SR 295 (pentaerythritol tetracrylate); SR 349 (triethoxylated bisphenol A diacrylate) SR 350 (trimethylolpropane trimethacrylate); SR 351 (trimethylolpropane triacrylate); SR 367 (Tetramethylolmethane tetramethacrylate); SR 368 (tris(2-acryloxy ethyl)isocyanurate triacrylate); SR 454 (ethoxylated(3)trimethylolpropane triacrylate); SR 9041 (dipentaerythritol pentaacrylate ester); and CN 120 (bisphenol A-epichlorohydrin diacrylate) (supplied by SARTOMER Company) and CN2301; CN2302; CN2303; CN 2304 (hyperbranched polyester acrylate).

Additional examples of commercially available acrylates include Kayarad® R-526 (hexanedioic acid, bis[2,2-dimethyl-3-[(1-oxo-2-propenyl)oxy]propyl]ester); SR 238 (hexamethylenediol diacrylate); SR 247 (neopentyl glycol diacrylate); SR 306 (tripropylene glycol diacrylate); CN 120 (bisphenol A-epichlorohydrin diacrylate) supplied by SARTOMER Company); Kayarad® R-551 (Bisphenol A polyethylene glycol diether diacrylate); Kayarad® R-712 (2,2′-Methylenebis[p-phenylenepoly(oxy-ethylene)oxy]diethyl diacrylate); Kayarad® R-604 (2-Propenoic acid, [2-[1,1-dimethyl-2-[(1-oxo-2-propenyl)oxy]ethyl]-5-ethyl-1,3-dioxan-5-yl]-methyl ester); Kayarad® R-684 (dimethyloltricyclodecane diacrylate); Kayarad® PET-30 (pentaerythritol triacrylate); GPO-303 (polyethylene glycol dimethacrylate); Kayarad® THE-330 (ethoxylated trimethylolpropane triacrylate); DPHA-2H, DPHA-2C and DPHA-21 (dipentaerythritol hexaacrylate); Kayarad® D-310 (DPHA); Kayarad® D-330 (DPHA); DPCA-20; DPCA-30; DPCA-60; DPCA-120; DN-0075; DN-2475; Kayarad® T-1420 (ditrimethylolpropane tetraacrylate); Kayarad® T-2020 (ditrimethylolpropane tetraacrylate); 1-2040; TPA-320; TPA-330; Kayarad® RP-1040 (pentaerythritol ethoxylate tetraacrylate); R-011; R-300; R-205 (methacrylic add, zinc salt, same as SR 634) (Nippon Kayaku Co., Ltd.); Aronix M-210; M-220; M-233; M-240; M-215; M-305; M-309; M-310; M-315; M-325; M-400; M-6200; M-6400 (Toagosei Chemical Industry Co, Ltd.); Light acrylate BP-4EA, BP-4PA, BP-2EA, BP-2PA, DCP-A (Kyoeisha Chemical Industry Co., Ltd.); New Frontier BPE-4, TEICA, BR-42M, GX-8345 (Daichi Kogyo Seiyaku Co., Ltd.); ASF-400 (Nippon Steel Chemical Co.); Ripoxy SP-1506, SP-1507, SP-1509, VR-77, SP-4010, SP-4060 (Showa Highpolymer Co., Ltd.); NK Ester A-BPE-4 (Shin-Nakamura Chemical Industry Co., Ltd.); SA-1002 (Mitsubishi Chemical Co., Ltd.); Viscoat-195, Viscoat-230, Viscoat-260, Viscoat-310, Viscoat-214HP, Viscoat-295, Viscoat-300, Viscoat-360,

Viscoat-GPT, Viscoat-400, Viscoat-700, Viscoat-540, Viscoat-3000, Viscoat-3700 (Osaka Organic Chemical Industry Co., Ltd.).

The photocurable composition of the present invention may include mixtures of the acrylate-containing compounds described above.

Additionally, the photocurable composition of the present invention may include other components, for example, stabilizers, modifiers, tougheners, antifoaming agents, leveling agents, thickening agents, flame retardants, antioxidants, pigments, dyes, fillers, and combinations thereof. Preferably, the inventive composition does not contain any elastomeric toughener such as core-shell polymers.

Compound having alcohol functionality and having low molecular weight (g)

Additionally, the composition of present invention may comprise a component (g) having alcohol functionality and having a molecular weight Mw equal or less than 1.500, preferably equal or less than 750 more preferably equal or less than 500. The component (g) may be monofunctional or polyfunctional with one, two or more OH groups. The hydroxyl groups can be either primary, secondary, of tertiary. This alcohol can be aliphatic, alicyclic, or aromatic. Inventors found that the presence of component (g) intensifies the phase separation of the higher molecular weight polyol.

In a preferred embodiment, component (g) is a polyol which can be linear or branched and is preferably selected from poly(oxytetramethylene), poly(oxypropylene), poly(oxyethylene), hydroxy-terminated polybutadiene.

In a further embodiment a combination of a polyol having a molecular weight Mw of 2.000 or higher as component (c) and of a hydroxyl-containing compound (g) having a molecular weight of 500 or below is used. Such combination intensifies the opacity of the cured composition.

Stabilizers which may be added to the photocurable composition to prevent viscosity build-up during usage include butylated hydroxytoluene (“BHT”), 2,6-Di-tent-butyl-4-hydroxytoluene, hindered amines, e.g., benzyl dimethyl amine (“BDMA”), N,N-Dimethylbenzylamine, and boron complexes.

### Preferred Embodiments

Preferably, the photocurable composition comprises:
a) 30-80% by weight of an epoxy-containing compound;
b) 5 to 65% by weight of a compound containing an oxetane ring in its molecule;
c) 1-25% by weight of a polyol having a molecular weight of 2000 or higher,
d) 0.2-10% by weight of a cationic photoinitiator;
e) 0.01-10% by weight of a free radical photoinitiator; and optionally
h) one or more stabilizers
   wherein the percent by weight is based on the total weight of the photocurable composition.

In a further embodiment the photocurable composition comprises
a) 30-80% by weight of an epoxy-containing compound;
b) 5 to 65%by weight of a compound containing an oxetane ring in its molecule;
c) 1-25% by weight of a polyol having a molecular weight Mw of 2.000 or higher,
d) 0.2-10% by weight of an antimony-free cationic photoinitiator;
e) 0.01-10% by weight of a free radical photoinitiator; and optionally
g) 0.5 to 10% by weight of a compound having an OH group and a molecular weight Mw below 1.000
h) one or more stabilizers
   wherein the percent by weight is based on the total weight of the photocurable composition.

In a further embodiment, the photocurable composition comprises:
a) 30 to 80% by weight of an epoxy-containing component with cycloaliphatic or perhydrogenated aromatic moieties,
b) 5 to 65% by weight of a compound containing an oxetane ring in its molecule;
c) 1 to 25% by weight of a polyol having a molecular weight above 2000,
d) an antimony-free cationic photoinitiator,
f) 5 to 60% of (meth)acrylic component with cycloaliphatic or perhydrogenated aromatic moieties,
   wherein the percent by weight is based on the total weight of the photocurable composition.

Besides forming 3-dimensional objects by conventional, laser directed stereolithography, compositions according to the invention can be used for other UV or visible non based 3-dimensional modeling (for example ink jet based systems and light valves exposed media). It can be used for photocurable coatings and inks, solder masks, cladding for optical fibres.

The invention further relates to a process for the preparation of three dimensional articles comprising:
A) applying a layer of the photocurable composition of present invention onto a surface;
B) exposing the layer imagewise to actinic radiation to form an imaged cross-section,
C) applying a second layer of the composition of present invention onto the previously exposed imaged cross-section;
D) exposing the thin layer from step (c) imagewise to actinic radiation to form an additional imaged cross-section, wherein the radiation causes curing of the second layer in the exposed areas and adhesion to the previously exposed cross-section, and
E) repeating steps (C) and (D) in order to build up a three-dimensional article.

Still a further subject of present invention is a three-dimensional article produced by the process described above.

The photocurable composition can be cured by coating a layer of the composition onto a surface and exposing the layer imagewise to actinic radiation of sufficient intensity to cause substantial curing of the layer in the exposed areas so that an imaged cross-section is formed. A thin layer of the photocurable composition may then be coated onto the prior imaged cross-section and exposed to actinic radiation of sufficient intensity to cause substantial curing of the thin layer and to cause adhesion to the prior imaged cross-section. This may be repeated a sufficient number of times for the purpose of building up a three-dimensional article having similar appearance and mechanical properties as ABS. As noted above, the article which may be produced from the photocurable composition of the present invention via stereolithography is an article having ABS-like properties. That is, the articles have similar color and light scattering characteristics as ABS and also feel like ABS. Preferably the photocurable composition, after curing by exposure to actinic radiation and optionally heat, has a tensile strength within the range from about 30-65 MPa, a tensile elongation at break within the range from about 2-110%, a flexural strength within the range from about 45-107 MPa, a flexural modulus within the range from about 1600-5900 MPa, a notched izod impact strength of less than 12 ft lb/in and a heat deflection temperature (at 0.46 MPa) within the range from about 68-140° C.

The photocurable compositions of the present invention are formulated to produce a clear, low viscosity liquid which upon photopolymerization during a stereolithography process, produces an opaque-white ABS-like article. Because the photocurable composition is clear, in contrast to opaque liquid resins, the partially completed article can be viewed under the photocurable composition's surface during the process. This allows one to change process parameters on subsequent layers to optimize the article during build or abort the building of the article altogether if necessary.

Stereolithography

A further aspect of the present invention includes a process for producing a three-dimensional article in sequential cross-sectional layers in accordance with a model of the article by forming a first layer of the photocurable composition; exposing the first layer to actinic radiation in a pattern corresponding to a respective cross-sectional layer of the model sufficient to harden the first layer in the imaged area; forming a second layer of the photocurable composition above the hardened first layer; exposing the second layer to actinic radiation in a pattern corresponding to a respective cross-sectional layer of the model sufficient to harden the second layer in the imaged area; and repeating the previous two steps to form successive layers as desired to form the three-dimensional article.

In principle, any stereolithography machine may be used to carry out the inventive method. Stereolithography equipment is commercially available from various manufacturers. Table I lists examples of commercial stereolithography equipment available from 3D Systems Corp. (Valencia, Calif.).

| MACHINE | WAVELENGTH (nm) |
|---|---|
| SLA ® 250 | 325 |
| SLA ® 500 | 351 |
| SLA ® 3500 | 355 |
| SLA ® 5000 | 355 |
| SLA ® 7000 | 355 |
| Viper si2 ™ | 355 |

Most preferably, the stereolithography process for producing a three-dimensional article from the photocurable composition of the present invention includes preparing the surface of the composition to form the first layer and then recoating the first layer and each successive layer of the three-dimensional article with a Zephyr™ recoater (3D Systems Corp., Valencia, Calif.), or an equivalent thereof.

### Examples

The general procedure used for preparing three-dimensional articles with stereolithography equipment is as follows. The photocurable composition is placed in a vat designed for use with the stereolithography equipment. The photocurable composition is poured into the vat within the machine at about 30° C. The surface of the composition, either in its entirety or in accordance with a predetermined pattern, is irradiated with a UV/VIS light source so that a layer of desired thickness is cured and solidified in the irradiated area. A new layer of the photocurable composition is formed on the solidified layer. The new layer is likewise irradiated over the entire surface or in a predetermined pattern. The newly solidified layer adheres to the underlying solidified layer. The layer formation step and the irradiation step are repeated until a green model of multiple solidified layers is produced.

A “green model” is a three-dimensional article initially formed by the stereolithography process of layering and photocuring, where typically the layers are not completely cured. This permits successive layers to better adhere by bonding together when further cured. “Green strength” is a general term for mechanical performance properties of a green model, including modulus, strain, strength, hardness, and layer-to-layer adhesion. For example, green strength may be reported by measuring flexural modulus (ASTM D 790). An object having low green strength may deform under its own weight, or may sag or collapse during curing.

The green model is then washed in tripropylene glycol monomethyl ether (“TPM”) and subsequently rinsed with water and dried with compressed air. The dried green model is next postcured with UV radiation in a postcure apparatus (“PCA”) for about 60-90 minutes. “Postcuring” is the process of reacting a green model to further cure the partially cured layers. A green model may be postcured by exposure to heat, actinic radiation, or both.

Mixing of Formulations

The formulations indicated in the following examples are prepared by mixing the components, with a stirrer at 20° C., until a homogeneous composition is obtained.

Testing Procedures

The photosensitivity of the compositions is determined on so-called window panes. In this determination, single-layer test specimens are produced using different laser energies, and the layer thicknesses are measured. The plotting of the resulting layer thickness on a graph against the logarithm of the irradiation energy used gives the “working curve”. The slope of this curve is termed Dp (depth of Penetration, in mils (1 mil=25.4 mm)). The energy value at which the curve passes through the x-axis is termed Ec (Critical Energy, in mJ/cm2). Cf. P. Jacobs, Rapid Prototyping and Manufacturing, Soc. Of Manufacturing Engineers, 1992, pp 270 ff.). For each example described, the inventors have chosen to report the energy required to fully polymerise a 0.10 mm layer, E4, in mJ/cm2.

The opacity of a cured sample is determined by measuring the lightness L* on a Minolta Spectrophotometer CM-2500d. L* varies from 0 (clear material) to 100 (opaque material). L* is measured on a 5×10×15 mm part built on a SLA7000 stereolithography apparatus, using the Dp and Ec calculated using the windowpanes procedure. The L* of a liquid resin is around 30.

Visual examination of cured parts has allowed the inventors to classify the formulations in one of the 3 following categories, according to their opacity/whiteness:
L*<65 solid part appears hazy or opalescent to the eye, but not white
65<L*<69 solid part appears white to the eye, but the opacity is not complete
L*>69 solid part appears white and completely opaque to the eye
L*=69 has been defined by the author as the value for which parts appear opaque and white to the eye.

Mechanical and thermal properties are determined on parts fabricated by 90 min UV cure in a silicon mold, unless otherwise stated.

Mechanical testing of fully cured parts was done according to ISO standards. Parts have been conditioned 3-5 days at 23° C. and 50% room humidity prior to testing.

| | ISO |
|---|---|
| | standard |
| Tensile properties | 527 |
| elongation to break, strength, modulus | |
| Flexural properties | 178 |
| Maximum strength, modulus | |
| Bend Notched Impact Resistance | 13586 |
| Fracture toughness (G1C), stress intensity coefficient (K1C) | |
| HDT at 1.8 MPa (or 0.45 MPa) | 75 |
| Heat deflection temperature under 1.80 MPa or 0.45 MPa load | |

The viscosity of the liquid mixtures (in mPa·S or cP) is determined at 30° C., using a Brookfield viscometer:

Components, other than (c1) and (c2) used in the examples:

| | Trade name | Chemical name | Source |
|---|---|---|---|
| epoxy | Uvacure 1500 | 3,4 epoxycyclohexylmethyl 3′, | Cytec |
| | | 4′epoxycyclohexanecarboxylate | |
| | Epalloy 5000 | Hydrogenated bisphenol A diglycidyl ether | CVC Chemicals |
| | Erisys GE 30 | Trimethylol propane triglycidyl ether | CVC Chemicals |
| oxetane | OXT-101 | 3-ethyl-3-hydroxymethyl oxetane | Toagosei |
| | OXT-121 | 1,4-bis[(3-ethyl-3- | Toagosei |
| | | oxetanylmethoxy)methylbenzene] | |
| Acrylate | CN120 | Bisphenol A epoxy diacrylate | Sartomer Co. |
| | SR833S | Tricyclodecane dimethanol diacrylate | Sartomer Co. |
| | SR349 | Ethoxylated₃ Bisphenol A Diacrylate | Sartomer Co. |
| | CN 2301 | Hyperbranched polyester acrylate oligomer | Sartomer Co. |
| Free radical | Irgacure 184 | 1-hydroxycyclohexyl phenyl ketone | Ciba Specialty |
| photoinitiator | | | Chemicals |
| Cationic | Esacure1064 | Mixture of PhS—(C6H4)—S + -Ph2 PF6— | Lamberti |
| photoinitiator | | and Ph2S + —(C6H4)—S—(C6H4)—S + Ph2 | |
| | | (PF6—)2 | |

| | | | | | OH |
|---|---|---|---|---|---|
| | | | | | equivalent |
| Component | | MW | | | weight |
| Trade name | Source | (g/mol) | Functionality | Classification | (g/mol) |
| Terathane 250 | Invista | 250 | 2 | primary | 125 |
| (polytetrahydrofuran) | | | | | |
| Terathane 1000 | Invista | 1000 | 2 | primary | 500 |
| (polytetrahydrofuran) | | | | | |
| Acclaim 12200 | BayerMaterial | 11200 | 2 | secondary | 10.0 |
| | Science | | | | |

### Examples 1 and 2

| Weight % | Ex. 1 | Ex. 2 |
|---|---|---|
| Epolead PB3600 | 18 | 18 |
| Terathane 250 | | 4 |
| Acclaim 12200 | 10 | 10 |
| OXT 121 | 65 | 61 |
| Irgacure 184 | 2 | 2 |
| Esacure 1064 | 5 | 5 |
| E4 (mJ/cm2) | 47.4 | 46.6 |
| L* | 81.7 | 84 |

| Weight % | Ex. 3 | Ex. 4 | Ex. 5 | Ex. 6 | Ex. 7 | Ex. 8 | Ex. 9 | Ex. 10 | Ex. 11 |
|---|---|---|---|---|---|---|---|---|---|
| Epalloy 5000 | 43 | 42 | 45 | 44.5 | 54 | 53 | 46 | 48 | 36 |
| Uvacure 1500 | | | | | | | | | |
| Erisys GE 30 | | | | | | | | | 10.8 |
| SR 349 | 28 | 28 | 28 | 28 | 20 | 20 | 28 | 28 | |
| SR 833 S | | | | | | | | | 18.1 |
| CN 2301 | | | | | | | | | 4.5 |
| Terathane 1000 | | | | | | | | | 5.6 |
| Terathane 250 | | 1 | | 0.5 | | 1 | 3 | 2 | |
| OXT 101 | 18 | 18 | 18 | 18 | 15 | 15 | 10 | 10 | 9 |
| Acclaim 12200 | 4 | 4 | 2 | 2 | 4 | 4 | 6 | 5 | 9 |
| Irgacure 184 | 2 | 2 | 2 | 2 | 2 | 2 | 2 | 2 | 2 |
| UVI 6976 | | | | | | | | | |
| Esacure 1064 | 5 | 5 | 5 | 5 | 5 | 5 | 5 | 5 | 5 |
| Viscosity at 30° C. (mPa · s) | / | 310 | / | 285 | / | 375 | 520 | 475 | / |
| E4 (mJ/cm2) | / | 27.4 | / | 33 | 34.2 | 30.0 | 28.7 | 26.3 | 76.9 |
| L* | / | 82.5 | / | 72.8 | 76.7 | 78.1 | 83.3 | 80.8 | 75 |

| | Ex. 4 | Ex. 8 |
|---|---|---|
| Tensile modulus (MPa) | 1685 | 1292 |
| Elong. At break (%) | 16.7 | 13.75 |
| Flexural modulus (MPa) | 1663 | 1263 |
| K1C (Mpa · √m) | 1.52 | 1.73 |
| G1C (J · m²) | 1167 | 1984 |
| HDT at 1.8 MPa (° C.) | 40 | 38.3 |

The compositions according to the invention can be employed quite generally for the production of cured products and can be used in the formulation suitable for the particular specific field of use, for example as photocurable resins for rapid prototyping or rapid manufacture, coating compositions for example in optical fibres, paints, pressing compositions, dipping resins, casting resins, impregnating resins, laminating resins, 1- or 2-component adhesives or matrix resins. Use in the field of aerospace, automotive, wind mill and sports equipment as photocurable laminating resins, hotmelt, composition for the Resin-Transfer-Moulding process, 1- or 2-component adhesives or matrix resins are also possible.

1. A photocurable composition comprising:
(a) 30-80% by weight of an epoxy-containing component
(b) 5 to 65% by weight of a compound containing an oxetane ring in its molecule;
(c) 1 to 25% by weight of a polyol having a molecular weight Mw of 2.000 or higher; and
(d) an antimony-free cationic photoinitiator;
wherein the percent by weight is based on the total weight of the photocurable composition.

2. The photocurable composition according to claim 1, wherein the cationic photoinitiator comprises a triarylsulfonium hexafluorophosphate salt.

3. The photocurable composition according to claim 2 wherein component (b) is selected from 3-ethyl-3-hydroxymethyloxetane, 3-(meth)allyloxymethyl-3-ethyloxetane, (3-ethyl-3-oxetanylmethoxy)methylbenzene, 4-fluoro-[1-(3-ethyl-3-oxetanylmethoxy)methyl]benzene, 4-methoxy-[1-(3-ethyl-3-oxetanylmethoxy)methyl]benzene, [1-(3-ethyl-3-oxetanylmethoxy)ethyl]phenyl ether, isobutoxymethyl(3-ethyl-3-oxetanylmethyl)ether, isobomyloxyethyl(3-ethyl-3-oxetanylmethyl)ether, isobomyl(3-ethyl-3-oxetanylmethyl)ether, 2-ethylhexyl(3-ethyl-3-oxetanylmethyl)ether, ethyldiethylene glycol(3-ethyl-3-oxetanylmethyl)ether, dicyclopentadiene(3-ethyl-3-oxetanylmethyl)ether, dicyclopentenyloxyethyl(3-ethyl-3-oxetanylmethyl)ether, dicyclopentenyl(3-ethyl-3-oxetanylmethyl)ether, tetrahydrofurfuryl(3-ethyl-3-oxetanylmethyl)ether, tetrabromophenyl(3-ethyl-3-oxetanylmethyl)-ether, 2-tetrabromophenoxyethyl(3-ethyl-3-oxetanylmethyl)ether, tribromophenyl(3-ethyl-3-oxetanylmethyl)ether, 2-tribromophenoxyethyl(3-ethyl-3-oxetanylmethyl)ether, 2-hydroxyethyl(3-ethyl-3-oxetanyl methyl)ether, 2-hydroxypropyl(3-ethyl-3-oxetanylmethyl)ether, butoxyethyl(3-ethyl-3-oxetanylmethyl)ether, pentachlorophenyl(3-ethyl-3-oxetanylmethyl)ether, pentabromophenyl(3-ethyl-3-oxetanylmethyl)ether, bornyl(3-ethyl-3-oxetanylmethyl)ether, and the like. Other examples of oxetane compounds suitable for use include trimethylene oxide, 3,3-dimethyloxetane, 3,3-dichloromethyloxetane, 3,3-[1,4-phenylene-bis(methyleneoxymethylene)]-bis(3-ethyl-oxetane), 3-ethyl-3-hydroxymethyl-oxetane, and bis-[(1-ethyl(3-oxetanyl)methyl)]ether, 3,7-bis(3-oxetanyl)-5-oxa-nonane, 3,3′-(1,3-(2-methylenyl)propanediylbis(oxymethylene))bis-(3-ethyloxetane), 1,4-bis[(3-ethyl-3-oxetanylmethoxy)methyl]benzene, 1,2-bis[(3-ethyl-3-oxetanylmethoxy)methyl]ethane, 1,3-bis[(3-ethyl-3-oxetanylmethoxy)-methy]propane, ethylene glycol bis(3-ethyl-3-oxetanylmethyl)ether, dicyclopentenyl bis(3-ethyl-3oxetanylmethyl)ether, triethylene glycol bis(3-ethyl-3-oxetanylmethyl)ether, tetraethylene glycol bis(3-ethyl-3-oxetanylmethyl)ether, tricyclo-decanediyldimethylene(3-ethyl-3-oxetanylmethyl)ether, trimethylolpropane tris(3-ethyl-3-oxetanylmethyl)ether, 1,4-bis(3-ethyl-3-oxetanylmethoxy)butane, 1,6-bis(3-ethyl-3-oxetanylmethoxy)hexane, pentaerythritol tris(3-ethyl-3-oxetanylmethyl)ether, pentaerythritol tetrakis(3-ethyl-3-oxetanylmethyl)ether, polyethylene glycol bis(3-ethyl-3-oxetanylmethyl)ether, dipentaerythritol hexakis(3-ethyl-3-oxetanylmethyl)ether, dipentaerythritol pentakis(3-ethyl-3-oxetanylmethyl)ether, dipentaerythritol tetrakis(3-ethyl-3-oxetanylmethyl)ether, caprolactone-modified dipentaerythritol hexakis(3-ethyl-3-oxetanylmethyl)ether, caprolactone-modified dipentaerythritol pentakis(3-ethyl-3-oxetanylmethyl)ether, ditrimethylolpropane tetrakis(3-ethyl-3-oxetanylmethyl)ether, EO-modified Bisphenol A bis(3-ethyl-3-oxetanylmethyl)ether, PO-modified Bisphenol A bis(3-ethyl-3-oxetanylmethyl)ether, EO-modified hydrogenated Bisphenol A bis(3-ethyl-3-oxetanylmethyl)ether, PO-modified hydrogenated Bisphenol A bis(3-ethyl-3-oxetanylmethyl)ether, EO-modified Bisphenol F (3-ethyl-3-oxetanylmethyl)ether, and any mixtures thereof.

4. The photocurable composition according to claim 2 wherein component (b) is present in an amount from 5 to 40% by weight, based on the total weight of the composition.

5. The photocurable composition of claim 1, wherein the polyol of component (c) is a polyether polyol.

6. The photocurable composition of claim 1 characterized in that the composition comprises as component (g) a compound having alcohol functionality and having a molecular weight Mw equal or less than 1.500.

7. The photocurable composition of claim 6, wherein the compound of component (g) is selected from poly(oxytetramethylene)polyol, poly(oxypropylene)polyol, poly(oxyethylene)polyol, hydroxy-terminated polybutadiene and hydroxy-terminated polysiloxane.

8. The photocurable composition according to claim 1 which further comprises as component (f) 5-40% by weight of a (meth)acrylate, based on the total weight of the composition.

9. The photocurable composition according to claim 1 which shows an L* value above 40.

10. The photocurable composition according to claim 1 characterized in that the composition comprises a combination of a polyol having a molecular weight Mw of 2.000 or higher as component (e) and of a hydroxyl-containing compound (g) having a molecular weight of 500 or below.

11. (canceled)

12. A photocurable composition comprising:
(a) 30 to 80% by weight of an epoxy-containing component with cycloaliphatic or perhydrogenated aromatic moieties,
(b) 5 to 65% by weight of a compound containing an oxetane ring in its molecule;
(c) 1 to 25% by weight of a polyol having a molecular weight Mw of 2.000 or higher,
(d) an antimony-free cationic photoinitiator,
(f) 5 to 60% of a (meth)acrylic component with cycloaliphatic, hydrogenated or perhydrogenated aromatic moieties,
wherein the percent by weight is based on the total weight of the photocurable composition.

13. The photocurable composition according to claim 12 further comprising
e) 0.01-10% by weight of a free radical photoinitiator; and optionally
g) 0.5 to 10% by weight of a compound having an OH group and a molecular weight Mw below than 1.000
h) one or more stabilizers
wherein the percent by weight is based on the total weight of the photo curable composition.

14. A process for the preparation of a three-dimensional articles comprising:
A) applying a layer of the photocurable composition of claim 1 onto a surface;
B) exposing the layer imagewise to actinic radiation to form an imaged cross-section;
C) applying a second layer of the photocurable composition of claim 1 onto the previously exposed imaged cross-section;
D) exposing the thin layer from step (C) imagewise to actinic radiation to form an additional imaged cross-section, wherein the radiation causes curing of the second layer in the exposed areas and adhesion to the previously exposed cross-section; and
E) repeating steps (C) and (D) in order to build up a three-dimensional article.

15. A three-dimensional article produced by the process of claim 14.

16. The photocurable composition according to claim 2 wherein component (b) is present in an amount from 5 to 25% by weight, based on the total weight of the composition.

17. The photocurable composition of claim 1 characterized in that the composition comprises as component (g) a compound having alcohol functionality and having a molecular weight Mw equal or less than 750.

18. The photocurable composition of claim 1 characterized in that the composition comprises as component (g) a compound having alcohol functionality and having a molecular weight Mw equal or less than 500.
